(19) United States
(12) Patent Application Publication
(10) Pub. No.: US 2016/0005990 A1
(43) Pub. Date: Jan. 7, 2016

(54) ORGANIC LIGHT-EMITTING DEVICE

(71) Applicant: Samsung Display Co., Ltd., Yongin-City (KR)

(72) Inventors: Sung Soo Lee, Suwon-si (KR); Young Mo Koo, Suwon-si (KR); Ok Keun Song, Hwaseong-si (KR); Woo Sik Jeon, Hwaseong-si (KR)

(21) Appl. No.: 14/584,105

(22) Filed: Dec. 29, 2014

(30) Foreign Application Priority Data
Jul. 2, 2014 (KR) 10-2014-0082496

(51) Int. Cl. H01L 51/50; H01L 51/52

(52) U.S. Cl. CPC H01L 51/5024; H01L 51/5206; H01L 51/5221; H01L 51/504; H01L 51/5088; H01L 2251/5384; H01L 2251/5346

(57) ABSTRACT

An organic light-emitting device comprises a first electrode, a second electrode, and an organic light-emitting layer disposed between the first electrode and the second electrode, and comprising at least a host material, a first dopant for emitting light of a first color and a second dopant for emitting light of a second color, which is different from the first color. The organic light-emitting layer is divided into a first region adjacent to the first electrode, a second region adjacent to the second electrode, and a third region between the first region and the second region. Only the second dopant is provided in at least one of the first region and the second region.

This application claims priority to Korean Patent Application No. 10-2014-0082496, filed on Jul. 2, 2014, in the Korean Intellectual Property Office, the disclosure of which is incorporated herein by reference in its entirety.

### BACKGROUND

1. Field

The disclosure relates to an organic light-emitting device.

2. Description of the Related Art

An organic light-emitting display device may include more than one organic light-emitting device. The organic light-emitting device may include an anode, a cathode, and at least one organic light-emitting layer disposed between the anode and the cathode. The organic light-emitting device may generate excitons by injecting holes provided by the anode and electrons provided by the cathode into the organic light-emitting layer so as for the holes and the electrons to be combined, and may generate light in response to the excitons returning to a ground state. In addition to the organic light-emitting layer between the anode and the cathode, the organic light-emitting device may also include a hole injection layer, a hole transport layer, an electron injection layer and an electron transport layer.

Organic light-emitting devices emitting white light, which are generally referred to as white organic light-emitting devices, may be implemented in various manners. Particularly, organic light-emitting devices with a tandem structure have been widely employed in consideration of their high stability and operability. A tandem-structure organic light-emitting device may include two organic light-emitting layers emitting light of different colors and a charge generation layer (CGL) interposed between the two organic light-emitting layers.

### SUMMARY

One aspect of the invention provides an organic light-emitting device, comprising: a first electrode; a second electrode disposed over the first electrode, wherein the first electrode is one of an anode and a cathode, and the second electrode is the other; and an organic light-emitting layer disposed between the first electrode and the second electrode, and comprising at least a host material, a first dopant for emitting light of a first color and a second dopant for emitting light of a second color, which is different from the first color, wherein the organic light-emitting layer is divided into a first region adjacent to the first electrode, a second region adjacent to the second electrode, and a third region between the first region and the second region; wherein only the second dopant is provided in at least one of the first region and the second region.

In the foregoing device, the first dopant may be provided in the third region. The first dopant in an amount of about 0.3 wt % to about 15 wt % may be present in the organic light-emitting layer. The second dopant may be provided in all three of the first region, the second region and the third region. The first dopant may be further provided in one of the first region and the second region. Only the first dopant may be provided in the third region. Only the second dopant may be provided in one of the first region and the second region and wherein none of the first dopant and the second dopant are provided in the other region where the second dopant is not provided. Only the second dopant may be provided in both the first region and the second region. The second dopant may be provided in only one of the first region and the second region and the first dopant is provided in the rest of the first organic light-emitting layer where the second dopant is not provided.

Still in the foregoing device, the second dopant in an amount of about 3 wt % to about 10 wt % may be present in the organic light-emitting layer. The first color may be red and the second color may be green. The first organic light-emitting layer may further include a host for the second dopant. The organic light-emitting layer may be further configured to receive holes and electrons to generate excitons, and wherein the number of excitons in the organic light-emitting layer gradually increases or decreases from a first edge of the first organic light-emitting layer facing the first electrode to a second edge of the first organic light-emitting layer facing the second electrode.

Further in the foregoing device, the organic light-emitting device may further comprise: an additional organic light-emitting layer disposed between the organic light-emitting layer and the first electrode or between the organic light-emitting layer and the second electrode; and a charge generation layer (CGL) disposed between the organic light-emitting layer and the additional organic light-emitting layer. Light emitted from the first organic light-emitting layer and light emitted from the second organic light-emitting layer may be configured to generate white light when mixed together.

Another aspect of the invention provides an organic light-emitting device, comprising: a first electrode; a second electrode configured to be disposed over the first electrode; a first organic light-emitting layer disposed between the first electrode and the second electrode, and at least a first host material, a first dopant for emitting light of a first color and a second dopant for emitting light of a second color, which is different from the first color; a second organic light-emitting layer disposed between the first organic light-emitting layer and the first electrode, and comprising a second host material and a third dopant for emitting light of a third color, which is different from the first color and the second color; and a charge generation layer (CGL) disposed between the first organic light-emitting layer and the second light-emitting layer, wherein the first dopant is provided only in a portion of the first organic light-emitting layer.

In the foregoing device, the first organic light-emitting layer may be divided into a first region adjacent to the CGL, a second region adjacent to the second electrode, and a third region between the first region and the second region and the first dopant is provided in the third region. The second dopant in an amount of about 0.3 wt % to about 15 wt % may be present in the first organic light-emitting layer. Only the second dopant may be provided in at least one of the first region and the second region. The first color is red, the second color is green and the third color is blue.

Embodiments of the invention provide an organic light-emitting device with a tandem structure, which has high color purity.

However, embodiments of the invention are not restricted to those set forth herein. The above and other embodiments of the invention will become more apparent to one of ordinary skill in the art to which the invention pertains by referencing the detailed description of the invention given below.

According to an embodiment of the invention, there is provided an organic light-emitting device comprising a first electrode, a second electrode configured to be disposed on the first electrode, and the second electrode and including a first dopant and a second dopant, which is different from the first dopant, wherein the first organic light-emitting layer is divided into a first region adjacent to the first electrode, a second region adjacent to the second electrode, and a third region between the first region and the second region and only the second dopant is provided in at least one of the first region and the second region.

In another aspect of the embodiment of the invention, there is provided an organic light-emitting device comprising a first electrode, a second electrode configured to be disposed on the first electrode, a first organic light-emitting layer configured to be disposed between the first electrode and the second electrode and including a first dopant and a second dopant, which is different from the first dopant; a second organic light-emitting layer configured to be disposed between the first organic light-emitting layer and the first electrode and including a third dopant, which is different from the first dopant and the second dopant, and a CGL configured to be disposed between the first organic light-emitting layer and the second light-emitting layer, wherein the first dopant is provided only in part of the first organic light-emitting layer.

According to the embodiments, it is possible to provide an organic light-emitting device with a tandem structure, which has high color purity.

Other features and embodiments will be apparent from the following detailed description, the drawings, and the claims.

### BRIEF DESCRIPTION OF THE DRAWINGS

FIG. 1 is a cross-sectional view of an organic light-emitting device according to an embodiment of the invention.

FIG. 2 is a cross-sectional view of portion A of FIG. 1.

FIGS. 3 through 11 are cross-sectional views of portions of organic light-emitting devices according to other embodiments of the invention, corresponding to portion A of FIG. 1.

### DETAILED DESCRIPTION OF THE EMBODIMENTS

The aspects and features of the present invention and methods for achieving the aspects and features will be apparent by referring to the embodiments to be described in detail with reference to the accompanying drawings. However, the present invention is not limited to the embodiments disclosed hereinafter, but can be implemented in diverse forms. The matters defined in the description, such as the detailed construction and elements, are nothing but specific details provided to assist those of ordinary skill in the art in a comprehensive understanding of the invention, and the present invention is only defined within the scope of the appended claims. In the entire description of the present invention, the same reference numerals are used for the same elements across various figures. In the drawings, sizes and relative sizes of layers and areas may be exaggerated for clarity in explanation.

The term “on” that is used to designate that an element is on another element located on a different layer or a layer includes both a case where an element is located directly on another element or a layer and a case where an element is located on another element via another layer or still another element.

Although the terms “first, second, and so forth” are used to describe diverse constituent elements, such constituent elements are not limited by the terms. The terms are used only to discriminate a constituent element from another constituent element. Accordingly, in the following description, a first constituent element may be a second constituent element.

Embodiments are described hereinafter with reference to the accompanying drawings.

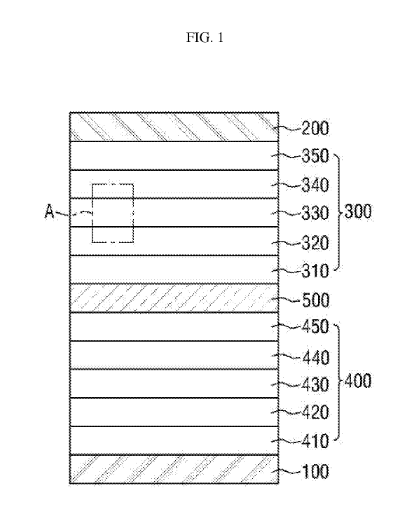

FIG. 1 is a cross-sectional view of an organic light-emitting device according to an embodiment of the invention. Referring to FIG. 1, the organic light-emitting device may include a first electrode 100, a second electrode 200, a first light-emitting unit 300, a second light-emitting unit 400, and a charge generation layer (CGL) 500.

The first electrode 100 may be disposed on an insulating substrate. The first electrode 100 may be an anode. The first electrode 100 may be formed of a conductive material with a high work function. In response to the organic light-emitting device 100 being of a bottom-emission type, the first electrode 100 may be formed of a material such as indium tin oxide (ITO), indium zinc oxide (IZO), ZnO or In₂O₃ or a deposition layer of the material. In response to the organic light-emitting device being of a top-emission type, the first electrode 100 may include a reflective layer, which is formed of Ag, Mg, Al, Pt, Pd, Au, Ni, Nd, Ir, Cr, Li, or Ca. Various modifications can be made to the structure of the first electrode 100 by using two or more different materials such that the first electrode 100 may have, for example, a double (or more)-layer structure. The first electrode 100 may be formed by sputtering using, for example, a fine metal mask (FMM).

The second electrode 200 may be disposed on and separate from the first electrode 100. The second electrode 200 may be a cathode. The second electrode 200 may be formed of a conductive material with a low work function. In an embodiment, the second electrode 200 may be formed of Ag, Mg, Al, Pt, Pd, Au, Ni, Nd, Ir, Cr, Li, or Ca.

The first light-emitting unit 300 may be disposed between the first electrode 100 and the second electrode 200. The first light-emitting unit 300 may directly contact the second electrode 200. The first light-emitting unit 300 may emit light of a first wavelength and light of a second wavelength, which is different from the first wavelength. The light of the first wavelength and the light of the second wavelength may be mixed together and may thus become yellow light. In an embodiment, the light of the first wavelength and the light of the second wavelength may be red light and green light, respectively, but the invention is not limited thereto.

The first light-emitting unit 300 may include a first hole injection layer 310, a first hole transport layer 320, a first organic light-emitting layer 330, a first electron transport layer 340 and a first electron injection layer 350.

The first hole injection layer 130 may be disposed on the first electrode 100. More specifically, the first hole injection layer 130 may directly contact the CGL 500. The first hole injection layer 310 may receive holes from the CGL 500. In an embodiment, the first hole injection layer 310 may be optional.

The first hole injection layer 310 may include a hole injection material. The hole injection material may be selected from one or more materials for injecting holes. For example, the materials for injecting holes may include a phthalocyanine compound, such as copper phthalocyanine, a starbust-type amine derivative, such as TCTA or m-MTDATA, and a conductive polymer, such as polyaniline/dodecylbenzenesulfonic acid (PANI/DBSA), poly(3,4-ethylenedioxythiophene)/poly(4-styrenesulfonate) (PEDOT/PSS), or polyaniline/camphor sulfonic acid (PANI/CSA) or polyaniline/poly(4-styrenesulfonate) (PANI/PSS), but the invention is not limited thereto.

The first hole transport layer 320 may be disposed on the first hole injection layer 310. More specifically, the first hole transport layer 320 may directly contact the first hole injection layer 310. The first hole transport layer 320 may receive holes from the first hole injection layer 310.

The first hole transport layer 320 may include a hole transport material. The hole transport material may be selected from one or more materials for transporting holes. For example, the materials for transporting holes may include 1,3,5-tricarbazolylbenzene, 4,4′-biscarbazolylbiphenyl, polyvinylcarbazole, m-biscarbazolylphenyl, 4,4′-biscarbazolyl-2,2′-dimethylbiphenyl, 4,4′,4″-tri(N-carbazolyl)triphenylamine, 1,3,5-tri(2-carbazolylphenyl)benzene, 1,3,5-tris(2-carbazolyl-5-methoxyphenyl)benzene, bis(4-carbazolylphenyl)silane, N,N′-bis(3-methylphenyl)-N,N′-diphenyl-[1,1-biphenyl]-4,4′diamine (TPD), N,N′-di(naphthalen-1-yl)-N,N′-diphenyl benzidine (NPD), N,N′-diphenyl-N,N′-bis(1-naphthyl)-(1,1′-biphenyl)-4,4′-diamine (NPB), poly(9,9-dioctylfluorene-co-N-(4-butylphenyl)diphenylamine) (TFB), and poly(9,9-dioctylfluorene-co-bis-(4-butylphenyl-bis-N,N-phenyl-1,4-phenylene diamine (PFB), but the invention is not limited thereto.

The first organic light-emitting layer 330 may be disposed on the first hole transport layer 320. More specifically, the first organic light-emitting layer 330 may directly contact the first hole transport layer 320. The first organic light-emitting layer 330 may receive holes from the first hole transport layer 320. The first organic light-emitting layer 330 may receive electrons from the first electron transport layer 340. The holes from the first hole transport layer 320 and the electrons from the first electron transport layer 340 may be combined together and may thus generate excitons. In response to the energy level of the excitons varying due to a transition from an excited state to a ground state, light may be emitted in a color corresponding to the amount of the variation of the energy level of the excitons.

The first organic light-emitting layer 330 may emit the light of the first wavelength and light of the second wavelength, which is different from the first wavelength. The light of the first wavelength and the light of the second wavelength may be mixed together and may thus become yellow light. In an embodiment, the light of the first wavelength and the light of the second wavelength may be red light and green light, respectively, but the invention is not limited thereto.

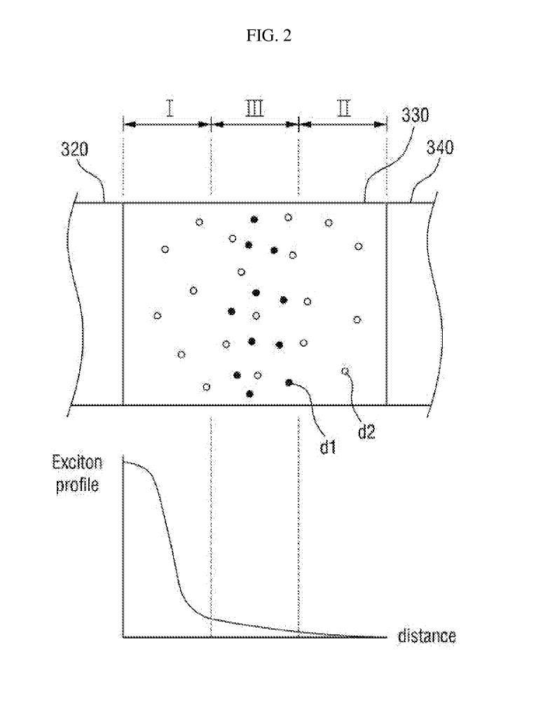

The first organic light-emitting layer 330 may include a first dopant d1 and a second dopant d2, which is different from the first dopant d1, as illustrated in FIG. 2. The first dopant d1 may emit light of the first wavelength, and the second dopant d2 may emit light of the second wavelength. The first organic light-emitting layer 330 may also include a host for the second dopant d2. The first organic light-emitting layer 330 will be described later in further detail.

The first electron transport layer 340 may be disposed on the first organic light-emitting layer 330. More specifically, the first electron transport layer 340 may directly contact the first organic light-emitting layer 330. The first electron transport layer 340 may receive electrons from the first electron injection layer 350.

The first electron transport layer 340 may include an electron transport material. The electron transport material may be selected from one or more materials for transporting electrons. For example, the materials for transporting electrons may include at least one of a pyrene-based material, a triazine-based material and an anthracene-based material, but the invention is not limited thereto. In an alternative example, the materials for transporting electrons may include quinoline derivatives, such as tris(8-quinolinorate)aluminum (Alq3), TAZ, or BAlq, but the invention is not limited thereto.

The first electron injection layer 350 may be disposed on the first electron transport layer 340. More specifically, the first electron injection layer 350 may directly contact the first electron transport layer 340. The first electron injection layer 350 may receive electrons from the second electrode 200. In an embodiment, the first electron injection layer 350 may be optional.

The first electron injection layer 350 may include an electron injection material. The electron injection material may be selected from one or more materials for injecting electrons. For example, the materials for injecting electrons may include at least one of LiF, LiQ, and NaQ, but the invention is not limited thereto. In an alternative example, the materials for injecting electrons may include NaCl, CsF, Li₂O, and BaO, but the invention is not limited thereto.

The second light-emitting unit 400 may be disposed between the first light-emitting unit 300 and the first electrode 100. The second light-emitting unit 400 may directly contact the first electrode 100. The second light-emitting unit 400 may emit light of a third wavelength, which is different from the first wavelength and the second wavelength. The light of the third wavelength may be blue light, but the invention is not limited thereto. The light of the first wavelength and the light of the second wavelength emitted from the first light-emitting unit 300 and the light of the third wavelength emitted from the second light-emitting unit 400 may be mixed together and may thus generate white light.

The second light-emitting unit 400 may include a second hole injection layer 410, a second hole transport layer 420, a second organic light-emitting layer 430, a second electron transport layer 440 and a second electron injection layer 450.

The second hole injection layer 410 may be disposed on the first electrode 100. More specifically, the second hole injection layer 410 may directly contact the first electrode 100. The second hole injection layer 410 may receive holes from the first electrode 100. In an embodiment, the second hole injection layer 410 may be optional.

The second hole injection layer 410 may include a hole injection material. The hole injection material may be selected from one or more materials for injecting holes. For example, the materials for injecting holes may include a phthalocyanine compound, such as copper phthalocyanine, a starbust-type amine derivative, such as TCTA or m-MTDATA, and a conductive polymer, such as PANI/DBSA, PEDOT/PSS, PANI/CSA or PANI/PSS, but the invention is not limited thereto. In an embodiment, the second hole injection layer 410 may be formed of the same material as the first hole injection layer 310.

The second hole transport layer 420 may be disposed on the second hole injection layer 410. More specifically, the second hole transport layer 420 may directly contact the second hole injection layer 410. The second hole transport layer 420 may receive holes from the second hole injection layer 410.

The second hole transport layer 420 may include a hole transport material. The hole transport material may be selected from one or more materials for transporting holes. For example, the materials for transporting holes may include 1,3,5-tricarbazolylbenzene, 4,4′-biscarbazolylbiphenyl, polyvinylcarbazole, m-biscarbazolylphenyl, 4,4′-biscarbazolyl-2,2′-dimethylbiphenyl, 4,4′,4″-tri(N-carbazolyl)triphenylamine, 1,3,5-tri(2-carbazolylphenyl)benzene, 1,3,5-tris(2-carbazolyl-5-methoxyphenyl)benzene, bis(4-carbazolylphenyl)silane, TPD, NPD, NPB, TFB, and PFB, but the invention is not limited thereto. In an embodiment, the second hole transport layer 420 may be formed of the same material as the first hole transport layer 320.

The second organic light-emitting layer 430 may be disposed on the second hole transport layer 420. More specifically, the second organic light-emitting layer 430 may directly contact the second hole transport layer 420. The second organic light-emitting layer 430 may receive holes from the second hole transport layer 420. The second organic light-emitting layer 430 may receive electrons from the second electron transport layer 440. The holes from the second hole transport layer 420 and the electrons from the second electron transport layer 440 may be combined together and may thus generate excitons. In response to the energy level of the excitons varying due to a transition from an excited state to a ground state, light may be emitted in a color corresponding to the amount of the variation of the energy level of the excitons.

The second organic light-emitting layer 430 may emit light of the third wavelength, which is different from the first wavelength and the second wavelength. The light of the third wavelength may be blue light, but the invention is not limited thereto. The light of the first wavelength and the light of the second wavelength emitted from the first light-emitting unit 300 and the light of the third wavelength emitted from the second light-emitting unit 400 may be mixed together and may thus generate white light.

The second organic light-emitting layer 430 may include a third dopant, which is different from the first dopant d1 and the second dopant d2. The third dopant may emit light of the third wavelength. The second organic light-emitting layer 430 may also include a host for the third dopant. In an embodiment, the third dopant may include F2Irpic, (F2ppy)2Ir(tmd), Ir(dfppz)3, and terfluorene, but the invention is not limited thereto. In an embodiment, the host for the third dopant may include at least one selected from an anthracene derivative and a carbazole-based compound. 9,10-(2-dinaphthyl)anthracene (ADN) may be used as the anthracene derivative, and 4,4′-bis(carbazol-9-yl)-biphenyl (CBP) may be used as the carbazole-based compound.

The second electron transport layer 440 may be disposed on the second organic light-emitting layer 430. More specifically, the second organic light-emitting layer 430 may directly contact the second organic light-emitting layer 430. The second electron transport layer 440 may receive electrons from the second electron injection layer 450.

The second electron transport layer 440 may include an electron transport material. The electron transport material may be selected from one or more materials for transporting electrons. For example, the materials for transporting electrons may include at least one of a pyrene-based material, a triazine-based material and an anthracene-based material, but the invention is not limited thereto. In an alternative example, the materials for transporting electrons may include quinoline derivatives, such as Alq3, TAZ, or BAlq, but the invention is not limited thereto. The second electron transport layer 440 may be formed of the same material as the first electron transport layer 340.

The second electron injection layer 450 may be disposed on the second electron transport layer 440. More specifically, the second electron injection layer 450 may directly contact the second electron transport layer 440. The second electron injection layer 450 may receive electrons from the CGL 500. In an embodiment, the second electron injection layer 450 may be optional.

The second electron injection layer 450 may include an electron injection material. The electron injection material may be selected from one or more materials for injecting electrons. For example, the materials for injecting electrons may include at least one of LiF, LiQ, and NaQ, but the invention is not limited thereto. In an alternative example, the materials for injecting electrons may include NaCl, CsF, Li₂O, and BaO, but the invention is not limited thereto. The second electron injection layer 450 may be formed of the same material as the first electron injection layer 350.

The CGL 500 may be disposed between the first light-emitting unit 300 and the second light-emitting unit 400. The CGL 500 may directly contact the first hole injection layer 310 of the first light-emitting unit 300 and the first electron injection layer 350 of the second light-emitting unit 400. The CGL 500 may generate charges, and may transmit the charges to the first light-emitting unit 300 and the second light-emitting unit 400.

The CGL 500 may include a first CGL and a second CGL. The first CGL may directly contact the first light-emitting unit 300. The first CGL may provide holes to the first hole injection layer 310 of the first light-emitting unit 300. The first CGL may be a p-type CGL. In an embodiment, the first CGL may include a single organic material such as hexaaza-triphenylene-hexanitrile (HATCN). In another embodiment, the first CGL may include a single inorganic material such as WO₃. In still another embodiment, the first CGL may include a hole transport material doped with a p-type organic material.

The second CGL may directly contact the second light-emitting unit 400. The second CGL may provide electrons to the second electron injection layer 450 of the second light-emitting unit 400. The second CGL may be an n-type CGL. In an embodiment, the second CGL may include an electron transport material doped with an alkali metal or an alkali earth metal. In another embodiment, the second CGL may include an electron transport material doped with an n-type organic material.

The first organic light-emitting layer 330 will hereinafter be described in further detail with reference to FIG. 2. FIG. 2 is a cross-sectional view of portion A of FIG. 1.

Referring to FIG. 2, the first organic light-emitting layer 330 may include the first dopant d1 and the second dopant d2, which is different from the first dopant d1. The first dopant d1 may emit light of the first wavelength, and the second dopant d2 may emit light of the second wavelength. The first organic light-emitting layer 330 may also include a host for the second dopant d2. In an embodiment, the first dopant d1 may include PtOEP, Ir(piq)3, Btp2Ir(acac), and DCJTB, but the invention is not limited thereto. In an embodiment, the second dopant d2 may include Ir(ppy)3 (where ppy denotes phenylpyridine), Ir(ppy)2(acac), Ir(mpyp)3, and C545T, but the invention is not limited thereto. In an embodiment, the host for the second dopant d2 may include at least one selected from an anthracene derivative and a carbozole-based compound, but the invention is not limited thereto. ADN may be used as the anthracene derivative, and CBP may be used as the carbazole-based compound.

The first organic light-emitting layer 330 may include a first region I, a second region II, and a third region III between the first region I and the second region II. More specifically, the first region I may be closest to the first hole transport layer 320 among the three regions, the second region II may be closest to the first electron transport layer 340 among the three regions, and the third region III may be a central part of the first organic light-emitting layer 330 between the first region I and the second region II.

Only the second dopant d2 may be provided in at least one of the first region I and the second region II. That is, the first dopant d1 is not provided in at least one of the first region I and the second region II, and may be provided only in part of the first organic light-emitting layer 330. As illustrated in FIG. 2, the second dopant d2 may be provided in all three of the first region I, the second region II and the third region III, whereas the first dopant d1 may be provided only in the third region III.

In embodiments, the first organic light emitting layer may include an extra sub-layer region which is interposed between the first electrode 100 and the first region I which includes only the second dopant d2. In this configuration, the extra sub-layer region does not include the first dopant. In embodiments, the first organic light emitting layer may include an extra sub-layer region interposed between the second electrode 200 and the second region II which includes only the second dopant d2. In this configuration, the extra sub-layer region does not include the first dopant.

In an embodiment, the first organic light-emitting layer 330 may contain the first dopant d1 in an amount of about 0.3 wt % to about 15 wt % and the second dopant d2 in an amount of about 3 wt % to about 10 wt %. In another embodiment, in response to the host for the second dopant d2 being deposited at a rate of about 100 Å/s, the first dopant d1 may be deposited at a rate of about 0.3 Å/s to about 15 Å/s, and the second dopant d2 may be deposited at a rate of about 3 Å/s to about 10 Å/s.

Referring to the graph at the bottom of FIG. 2, the exciton profile in the first organic light-emitting layer 330 may decrease from a first edge of the first organic light-emitting layer 330 adjacent to the first hole transport layer 320 to a second edge of the first organic light-emitting layer 330 adjacent to the first electron transport layer 340. That is, most excitons generated in the first organic light-emitting layer 330 may be located along the interface between the first hole transport layer 320 and the first organic light-emitting layer 330. In other words, the number of excitons generated in the first organic light-emitting layer 330 may gradually decrease from the first region I to the third region III and from the third region III to the second region II.

To realize an organic light-emitting device with a tandem structure, the first organic light-emitting layer 330 may be configured to emit yellow light. However, in a case in which the first organic light-emitting layer 330 emits yellow non-mixed light, an organic light-emitting device with high color purity would not be able to be obtained. That is, in a case in which the first organic light-emitting layer 330 includes a single dopant emitting yellow light, the color purity of an organic light-emitting device may be lowered during the separation of white light emitted from the organic light-emitting device into red light and green light with the use of a color filter.

On the other hand, in response to the first organic light-emitting layer 330 including the first dopant d1, which emits red light, and the second dopant d2, which emits green light, the color purity of an organic light-emitting device does not decrease even when separating white light emitted from the organic light-emitting device into red light and green light with the use of a color filter.

In a case in which the first dopant d1, which emits red light, and the second dopant d2, which emits green light, are distributed throughout the entire first organic light-emitting layer 330, the amount of the first dopant d1 may need to be adjusted to be about 0.3 wt % or lower. In a case in which the first organic light-emitting layer 330 contains more than about 0.3 wt % of the first dopant d1, energy may all be transmitted to the first dopant d1, which has a low energy level, and as a result, only red light may be emitted from the first organic light-emitting layer 330.

However, it may be highly difficult to set the concentration of the first dopant d1 to be as low as about 0.3 wt % during the formation of the first organic light-emitting layer 330 due to the limited sensing capability of a sensor for measuring the amount of a dopant.

Therefore, according to an embodiment of the invention, an organic light-emitting device with high color purity may be provided by providing the first dopant d1 only in a limited region or sub-layer of the first organic light-emitting layer 330 where a small number of excitons are generated at a concentration of about 0.3 wt % to about 15 wt %. That is, only the second dopant d2 may be provided in a region where there are many excitons, for example, the first region I, and the third dopant may be provided in a region where there are not many excitons, for example, the third region III. As a result, an organic light-emitting device having not only a high concentration of the first dopant d1, but also a high color purity, may be provided.

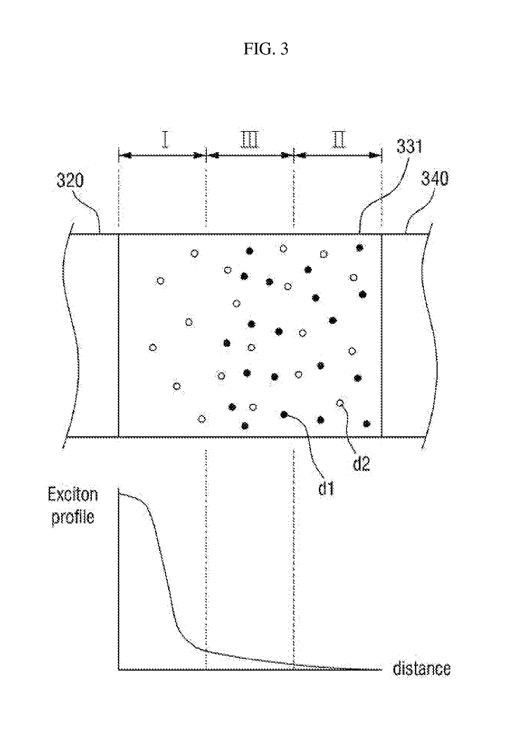

FIGS. 3 through 11 are cross-sectional views of portions of organic light-emitting devices according to other embodiments of the invention, corresponding to portion A of FIG. 1. In FIGS. 1 to 11, like reference numerals indicate like elements, and thus, detailed descriptions thereof will be omitted.

In the embodiments of FIGS. 3 to 6, like in the embodiment of FIGS. 1 and 2, the exciton profile in a first organic light-emitting layer 331, 332, 333 of 334 may gradually decrease from a first edge of the first organic light-emitting layer 331, 332, 333 of 334 adjacent to a first hole transport layer 320 to a second edge of the first organic light-emitting layer 331, 332, 333 of 334 adjacent to a first electron transport layer 340.

Referring to FIG. 3, a first dopant d1 may be provided not only in a third region III, but also in a second region II of the first organic light-emitting layer 331. That is, the first dopant d1 may be provided in the entire first organic light-emitting layer 331 except for the first region I.

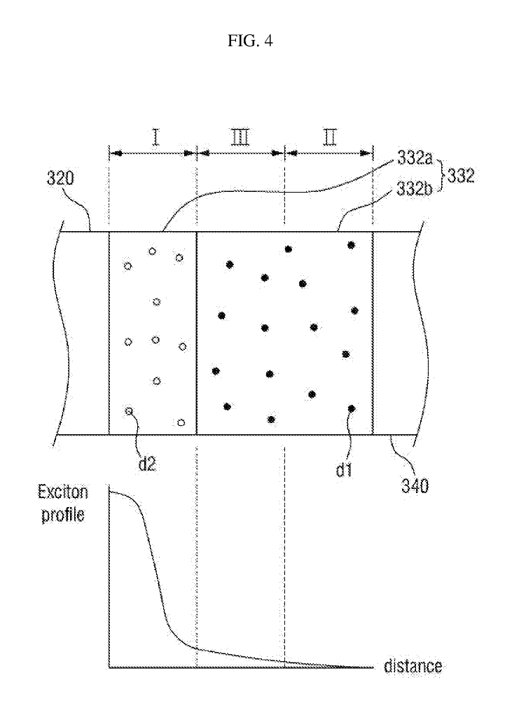

Referring to FIG. 4, the first organic light-emitting layer 332 may include a first sub-layer 332a, which is located in a first region I, and a second sub-layer 332b, which is located in a second region II and a third region III. The first sub-layer 332a may include a second dopant d2 only, and the second sub-layer 332b may include a first dopant d1 only.

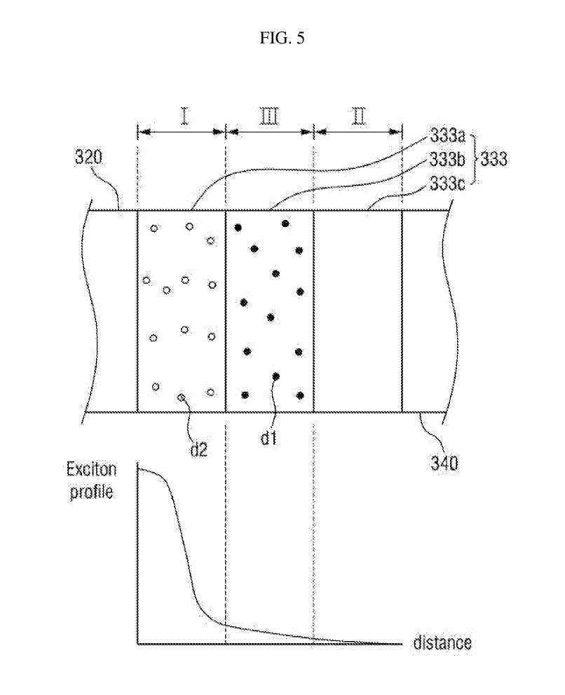

Referring to FIG. 5, the first organic light-emitting layer 333 may include a first sub-layer 333a, which is located in a first region I, a second sub-layer 333b, which is located in a third region III, and a third sub-layer 333c, which is located in a second region II. The first sub-layer 333a may include a second dopant d2 only, and the second sub-layer 333b may include a first dopant d1 only. The third sub-layer 333c may include neither the first dopant d1 nor the second dopant d2. That is, the third sub-layer 333c may include a host for the second dopant d2 only.

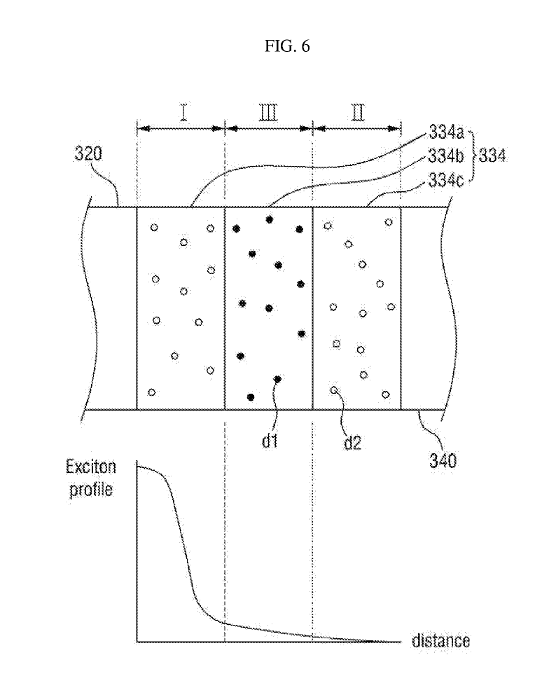

Referring to FIG. 6, the first organic light-emitting layer 334 may include a first sub-layer 334a, which is located in a first region I, a second sub-layer 334b, which is located in a third region III, and a third sub-layer 334c, which is located in a second region II. The first sub-layer 334a may include a second dopant d2 only, the second sub-layer 334b may include a first dopant d1 only, and the third sub-layer 334c may include the second dopant d2 only.

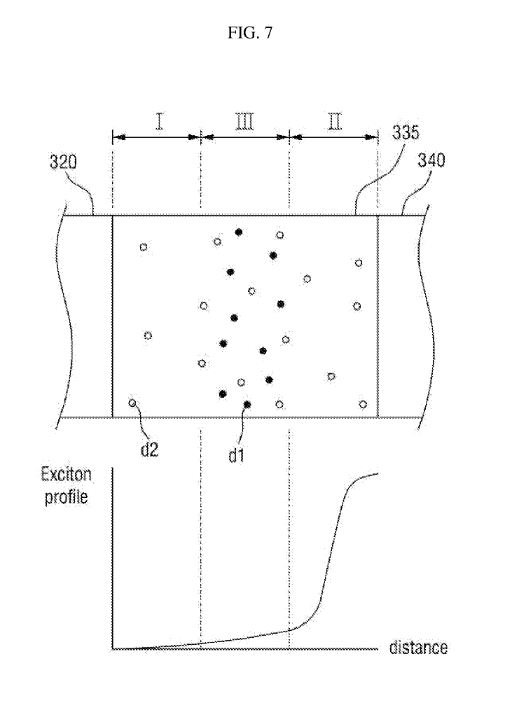

In the embodiments of FIGS. 7 to 11, unlike in the embodiment of FIGS. 1 and 2, the exciton profile in a first organic light-emitting layer 335, 336, 337, 338 of 339 may gradually increase from a first edge of the first organic light-emitting layer 335, 336, 337, 338 of 339 adjacent to a first hole transport layer 320 to a second edge of the first organic light-emitting layer 335, 336, 337, 338 of 339 adjacent to a first electron transport layer 340.

Referring to FIG. 7, a second dopant d2 may be provided in all three of a first region I, a second region II and a third region III, and a first dopant d1 may be provided only in the third region III. That is, the first organic light-emitting layer 335 may be substantially the same as the first organic light-emitting layer 330 of FIGS. 1 and 2. According to the embodiment of FIG. 7, an organic light-emitting device having not only a high concentration of the first dopant d1, but also a high color purity, may be provided, even though the exciton profile in the first organic light-emitting layer 335 is inverted from the exciton profile in the first organic light-emitting layer 330.

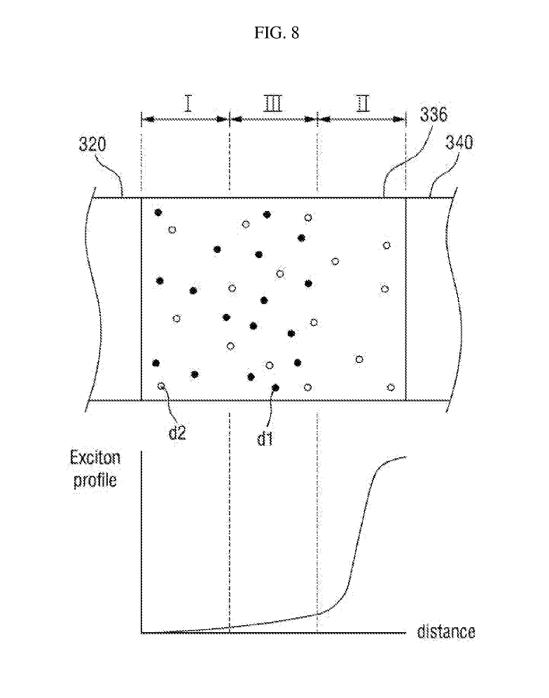

Referring to FIG. 8, a first dopant d1 may be provided only in a third region III, but also in a first region I. That is, the first dopant d1 may be distributed in the entire first organic light-emitting layer 336 except for a second region II.

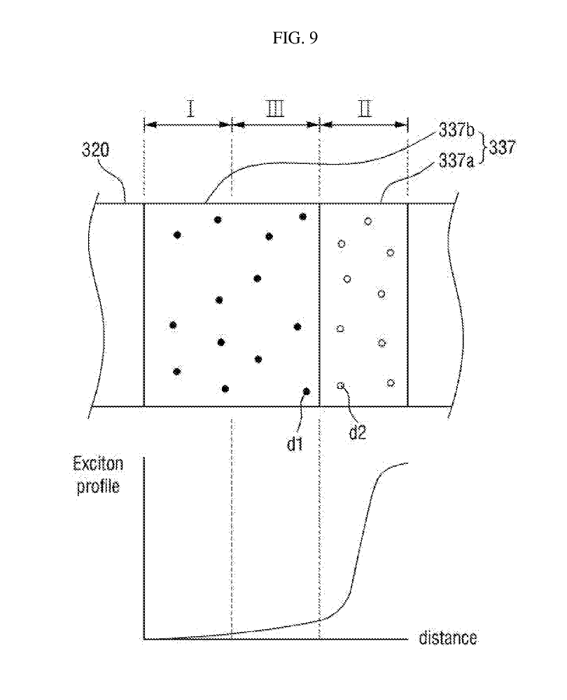

Referring to FIG. 9, the first organic light-emitting layer 337 may include a first sub-layer 337a, which is located in a second region II, and a second sub-layer 337b, which is located in a first region I and a third region III. The first sub-layer 337a may include a second dopant d2 only, and the second sub-layer 337b may include a first dopant d1 only.

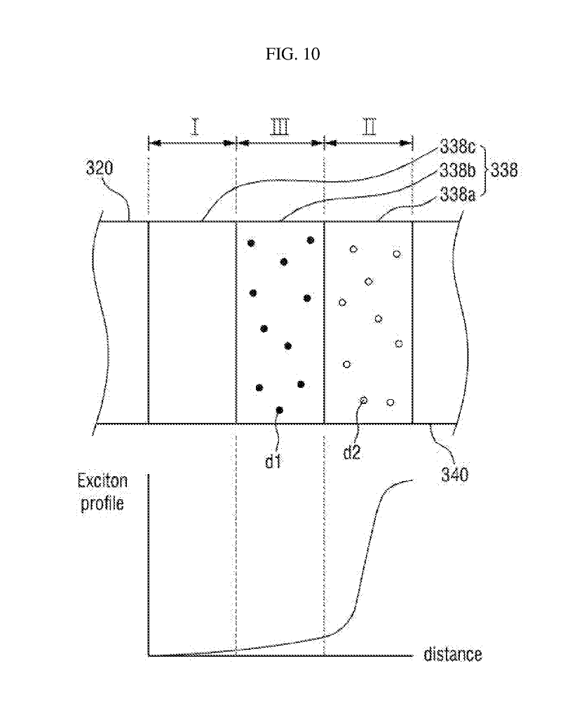

Referring to FIG. 10, the first organic light-emitting layer 338 may include a first sub-layer 338a, which is located in a second region II, a second sub-layer 338b, which is located in a third region III, and a third sub-layer 338c, which is located in a first region I. The first sub-layer 338a may include a second dopant d2 only, and the second sub-layer 338b may include a first dopant d1 only. The third sub-layer 338c may include neither the first dopant d1 nor the second dopant d2. That is, the third sub-layer 338c may include a host for the second dopant d2 only.

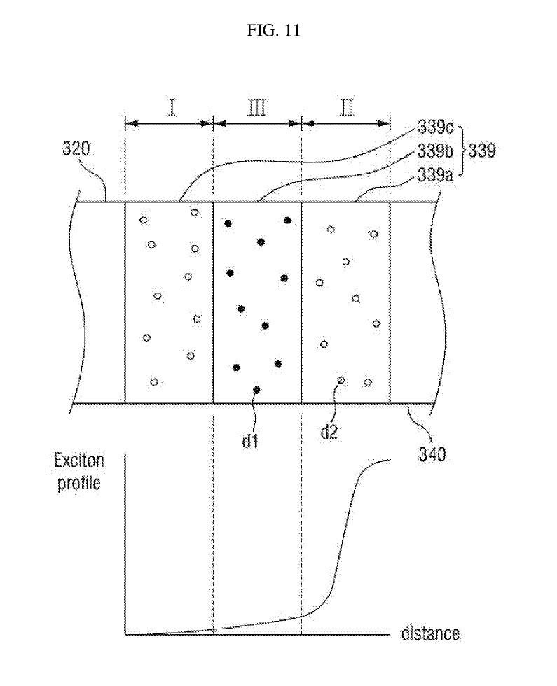

Referring to FIG. 11, the first organic light-emitting layer 339 may include a first sub-layer 339a, which is located in a second region II, a second sub-layer 339b, which is located in a third region III, and a third sub-layer 339c, which is located in a first region I. The first sub-layer 339a may include a second dopant d2 only, the second sub-layer 339b may include a first dopant d1 only, and the third sub-layer 339c may include the second dopant d2 only. That is, the first organic light-emitting layer 339 may be substantially the same as the first organic light-emitting layer 334 of FIG. 6. According to the embodiment of FIG. 11, an organic light-emitting device having not only a high concentration of the first dopant d1, but also a high color purity, may be provided, even though the exciton profile in the first organic light-emitting layer 339 is inverted from the exciton profile in the first organic light-emitting layer 334.

While the invention has been particularly shown and described with reference to embodiments thereof, it will be understood by those of ordinary skill in the art that various changes may be made therein without departing from the spirit and scope of the invention as defined by the following claims. The embodiments should be considered in a descriptive sense only and not for purposes of limitation.

1. An organic light-emitting device, comprising:
a first electrode;
a second electrode; and
an organic light-emitting layer disposed between the first electrode and the second electrode, the organic light-emitting layer comprising at least a host material, a first dopant for a first color and a second dopant for a second color different from the first color,
wherein the organic light-emitting layer comprises a first region and a second region and a third region between the first region and the second region, the first region being interposed between the first electrode and the third region, the second region being interposed between the third region and the second electrode;
wherein the first region does not comprise the first dopant, and the third region comprises both the first and second dopants.

2. The organic light-emitting device of claim 1, wherein the second region does not comprise the first dopant.

3. The organic light-emitting device of claim 2, wherein the first dopant is present in an amount of about 0.3 wt % to about 15 wt % in the organic light-emitting layer.

4. The organic light-emitting device of claim 2, wherein the second dopant is provided in each of the first region, the second region and the third region.

5. The organic light-emitting device of claim 1, wherein the second region comprises the first dopant.

6. The organic light-emitting device of claim 2, wherein the first dopant is provided only in the third region within the organic light-emitting layer.

7. The organic light-emitting device of claim 1, wherein each of the first region and the second region does not comprise the first dopant.

8. The organic light-emitting device of claim 7, wherein each of the first region and the second region comprises the second dopant.

9. (canceled)

10. The organic light-emitting device of claim 1, wherein the second dopant is present in an amount of about 3 wt % to about 10 wt % in the organic light-emitting layer.

11. The organic light-emitting device of claim 1, wherein the first color is red and the second color is green.

12. (canceled)

13. The organic light-emitting device of claim 1, wherein the organic light-emitting layer is further configured to receive holes and electrons to generate excitons, and wherein the number of excitons in the organic light-emitting layer gradually increases or decreases from a first edge of the first organic light-emitting layer facing the first electrode to a second edge of the first organic light-emitting layer facing the second electrode.

14. The organic light-emitting device of claim 1, further comprising:
an additional organic light-emitting layer disposed between the organic light-emitting layer and the first electrode or between the organic light-emitting layer and the second electrode; and
a charge generation layer (CGL) disposed between the organic light-emitting layer and the additional organic light-emitting layer.

15. The organic light-emitting device of claim 14, wherein the device is configured such that light emitted from the first organic light-emitting layer and light emitted from the second organic light-emitting layer are to be mixed for white light.

16. An organic light-emitting device, comprising:
a first electrode;
a second electrode;
a first organic light-emitting layer disposed between the first electrode and the second electrode, the first organic light-emitting layer comprising a first dopant for a first color and a second dopant for a second color different from the first color;
a second organic light-emitting layer disposed between the first organic light-emitting layer and the first electrode, the second organic light-emitting layer comprising a third dopant for a third color different from the first color and the second color; and
a charge generation layer (CGL) disposed between the first organic light-emitting layer and the second light-emitting layer,
wherein the first organic light-emitting layer comprises a first region, a second region and a third region interposed between the first and second regions,
wherein the first region does not comprise the first dopant, and the third region that comprises both the first and second dopants.

17. The organic light-emitting device of claim 16, wherein the first region is interposed between the third region and the CGL.

18. The organic light-emitting device of claim 17, wherein the second dopant is present in an amount of about 0.3 wt % to about 15 wt % in the first organic light-emitting layer.

19. The organic light-emitting device of claim 17, wherein each of the first region and the second region comprises the second dopant and does not comprise the first dopant.

20. The organic light-emitting device of claim 16, wherein the first color is red, the second color is green and the third color is blue.

21. The organic light-emitting device of claim 1, wherein an exciton profile of the third region is smaller than an exciton profile of the first region.
